(19) United States
(12) Patent Application Publication
(10) Pub. No.: US 2010/0159636 A1
(43) Pub. Date: Jun. 24, 2010

(54) METHOD OF FORMING PHASE CHANGE LAYER AND METHOD OF MANUFCTURING PHASE CHANGE MEMORY DEVICE USING THE SAME

(76) Inventors: Hyun Phill KIM, Gyeonggi-do (KR); Il Cheol RHO, Gyeonggi-do (KR); Jie Won CHUNG, Seoul (KR)

Correspondence Address: LADAS & PARRY LLP, 224 SOUTH MICHIGAN AVENUE, SUITE 1600, CHICAGO, IL, 60604, US

(21) Appl. No.: 12/539,010

(22) Filed: Aug. 11, 2009

(30) Foreign Application Priority Data
Dec. 24, 2008 (KR) 10-2008-0133921

(51) Int. Cl. H01L 21/06

(52) U.S. Cl. 438/102; 257/E21.068

(57) ABSTRACT

Disclosed herein are a method of forming a stable phase change layer without generating seams, and a method of manufacturing phase change memory device using the same. In the method of forming a phase change layer, the phase change layer is formed by performing a first deposition process of a phase change material, performing an etching process so as to etch the phase change material, and performing a second deposition process of a phase change material on the etched phase change material. The etching process and the second deposition process are performed a predetermined number of times.

### CROSS-REFERENCES TO RELATED APPLICATIONS

The present application claims priority according to Korean patent application number 10-2008-0133921 filed on Dec. 24, 2008, which is incorporated herein by reference in its entirety.

### BACKGROUND OF THE INVENTION

The present invention relates generally to a method of manufacturing a phase change memory device, and more particularly, to a method of forming a phase change layer, in which a phase change layer can be filled without generating seams, and a method of manufacturing a phase change memory device using the same.

With the design constraints of convention non-volatile memory devices in mind, research has been undertaken to develop memory devices having the characteristics of conventional non-volatile memory devices without certain drawbacks associated with the conventional non-volatile memory devices. One such memory device under development is the phase change memory device, which is considered as having potential due to its simple structure and the ease at which the device can be highly-integrated.

One of the most important design factors that must be given consideration when developing a phase change memory device is the level of reset current required to change the phase change layer from a crystalline state to an amorphous state. The lower the reset current, the faster the phase transition of the phase change layer proceeds. As a result, the current characteristics of a phase change memory device are improved with a decreased reset current.

Accordingly, current research in the area of phase change memory includes research into methods for decreasing the reset current of a phase change memory device. For example, a phase change layer having a confined or semi-confined structure in which a phase change material is filled in holes is currently being researched. When the phase change layer having a confined or semi-confined structure is applied to a phase change memory device, the phase change memory device can realize a reset current lower than that of a phase change layer having a pattern structure.

Generally, a method of forming a phase change layer having a confined or semi-confined structure is performed through a sputter deposition process or a chemical vapor deposition (CVD) process. However, a phase change layer formed through the sputter deposition process has poor step coverage characteristics, and it is therefore very possible to generate seams in holes when a phase change material is filled in the holes. If the seams are exposed to cleaning chemicals or etching gases during subsequent processes, the properties of the phase change layer can be deteriorated.

A phase change layer formed through a chemical vapor deposition (CVD) is generally regarded as having better step coverage characteristics than a phase change layer formed through a sputter deposition process; however, in a chemical vapor deposition (CVD) process, certain phenomena having a detrimental influence on device characteristics, such as the change in composition ratio of a phase change material, the weakening in adhesivity of a phase change material and the like, can occur.

### SUMMARY OF THE INVENTION

Embodiments of the present invention include a method of manufacturing a phase change layer capable of having a stable confined or semi-confined structure without generating seams, and a method of manufacturing a phase change memory device using the same.

Also, embodiments of the present invention include a method of forming a phase change layer having a stable confined or semi-confined structure without changing its composition ratio, and a method of manufacturing a phase change memory device using the same.

In one aspect of the present invention, a method of forming a phase change layer comprises performing a first deposition process of a phase change material, performing an etching process so as to etch the phase change material; and performing a second deposition process of a phase change material on the etched phase change material, wherein the etching process and the second deposition process are performed N times.

N may be in the range of 2˜5 times.

The etching process is may be conducted as an RF-etching process.

The RF-etching process may be conducted using an inert gas.

The inert gas may comprise Ar.

The RF-etching process may be performed using a bias power in the range of 50˜500 W.

The RF-etching process may be performed using a plasma power of 400 W and a bias power of 500 W.

The RF-etching process may also be performed using a plasma power of 400 W and a bias power of 300 W.

The RF-etching process may also be performed using a plasma power of 400 W and a bias power of 100 W.

The phase change layer may comprise at least two different elements selected among Ge, Sb and Te, or may also include any one of In—Sb—Te and Ge—Bi—Te.

In another aspect of the present invention, a method of manufacturing a phase change memory device comprises forming a lower electrode; forming an interlayer dielectric on the lower electrode, the interlayer dielectric having a hole; forming a phase change layer to completely fill the hole; and forming an upper electrode on the phase change layer. Forming the phase change layer comprises the steps of depositing a phase change layer on the interlayer dielectric including in the hole, etching the phase change layer formed on the interlayer dielectric, and depositing an additional phase change layer on the etched phase change layer. The step of etching the phase change layer and depositing the additional phase change layer are formed N times.

N may be 2˜5 times.

The hole may be formed to a depth in the range of 300˜1500 Å.

The etching process may be an RF-etching process.

The RF-etching process is conducted using an inert gas.

The inert gas comprises Ar.

The RF-etching process may be performed using a bias power of 50˜500 W.

The RF-etching process may also be performed using a plasma power of 400 W and a bias power of 500 W.

The RF-etching process may also be performed using a plasma power of 400 W and a bias power of 300 W.

The RF-etching process may also be performed using a plasma power of 400 W and a bias power of 100 W.

The phase change layers may include at least two different elements selected among Ge, Sb and Te, or may also include any one of In—Sb—Te and Ge—Bi—Te.

The phase change layer may be formed to have a confined or semi-confined structure.

### BRIEF DESCRIPTION OF THE DRAWINGS

FIGS. 1A through 1F are cross-sectional views shown for illustrating the processes of a method of manufacturing a phase change memory device in accordance with an embodiment of the present invention.

FIGS. 2A to 2C are plan views showing a state of the phase change layer after an RF etching process in the phase change memory device in accordance with the embodiment of the present invention shown in FIGS. 1A through 1C.

FIG. 3 is a graph showing the change in material properties of a phase change layer according to an embodiment the present invention.

FIGS. 4A through 4F are cross-sectional views shown for illustrating the processes of a method of manufacturing a phase change memory device in accordance with another embodiment of the present invention.

### DESCRIPTION OF SPECIFIC EMBODIMENTS

In the present invention a method in which a first deposition process, an etching process and a second deposition process are performed, with at least the etching process and the second deposition process being performed N times, to form a phase change layer having a confined or semi-confined structure. Accordingly, in the present invention, a phase change material can be filled in holes without changing the composition ratio of the phase change material and without generating seams. As a result, a phase change layer having a confined or semi-confined structure can be formed without limiting the ability of the phase change material to be filled in the holes, thereby decreasing the required reset current.

Hereinafter, specific embodiments of the present invention will be described with reference to the accompanying drawings.

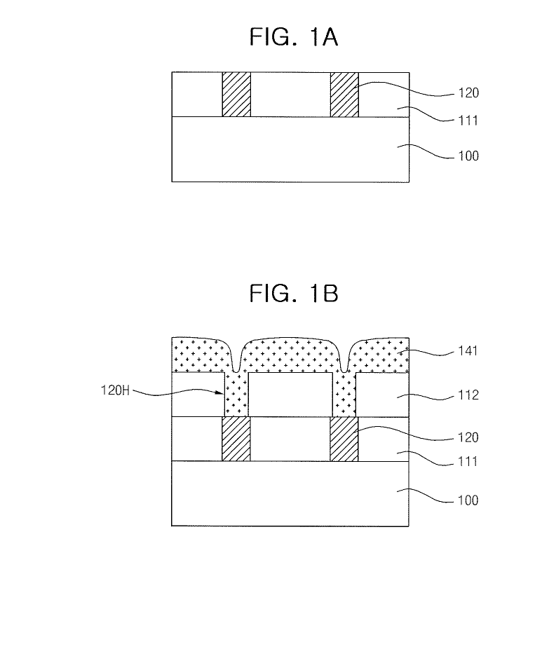

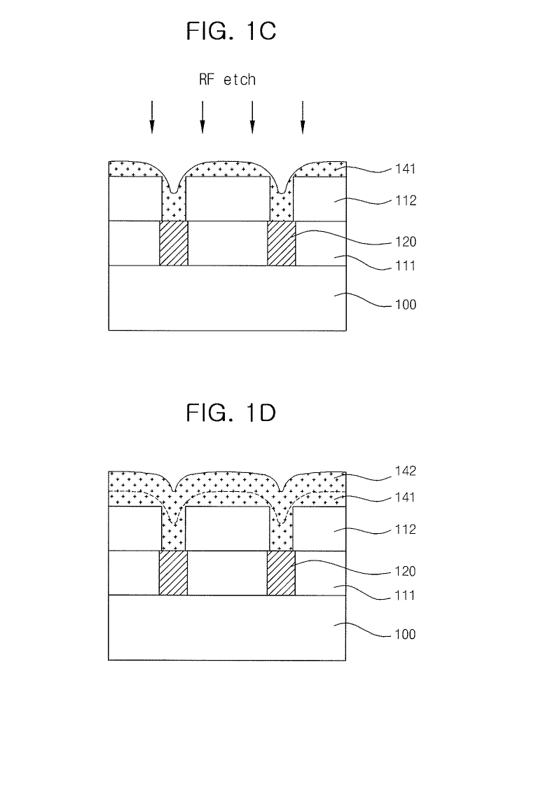

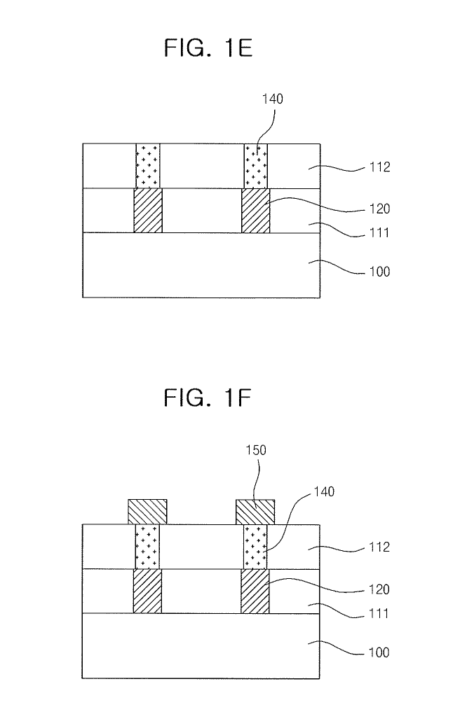

FIGS. 1A through 1F are cross-sectional views shown for illustrating the processes of a method of manufacturing a phase change memory device in accordance with an embodiment of the present invention.

Referring to FIG. 1A, a first interlayer dielectric 111 is formed on a semiconductor substrate 100 having a base layer (not shown). In an embodiment, the semiconductor substrate 100 includes a silicon substrate in which an n-type impurity region is formed, and the base layer includes a switching device composed of diodes. The first interlayer dielectric 111 is etched so as to define contact holes; and subsequently, the contact holes are filled with a lower electrode material. The lower electrode material is planarized to expose the first interlayer dielectric 111 so as to form lower electrodes 120 coming into contact with the base layer. The lower electrodes 120 serve as heaters for emitting the heat generated at the time of phase change. In an embodiment, the lower electrodes are formed of any one of W, TiN, WN, MoN, NbN, TiSiN, TiAlN, TiBN, ZrSiN, WSiN, WBN, ZrAlN, TaSiN, TaAlN, Ti, W, Ta, Pt, TiSi, TaSi, TiW, TiAlON, WON, TaON and IrO₂.

Referring to FIG. 1B, a second interlayer dielectric 112 is formed on the first interlayer dielectric 111 including the lower electrodes 120; and subsequently, the second interlayer dielectric 112 is etched so as to form holes 120H exposing a portion of the surfaces of the lower electrodes 120, respectively. The holes 120H are formed to a depth in the range of 300˜1500 Å, and preferably, the holes 120H are formed to a depth in the range of 1000˜1500 Å. A phase change layer is filled within the holes 120H in subsequent processes. Then, a first phase change film 141 is deposited on the second interlayer dielectric 112 to fill the holes. Preferably, the first phase change film 141 is deposited to a thickness of 400 Å or more. The first phase change film 141 is deposited using at least two different elements selected among Ge, Sb and Te or is deposited using any one of In—Sb—Te and Ge—Bi—Te. As shown in the embodiment of the present invention shown in FIG. 1B, recesses are formed in the first phase change film 141 over the holes.

Referring to FIG. 1C, an RF-etching process is conducted on the first phase change film 141. The RF-etching process is performed using an inert gas under the condition of a bias power of 50˜500 W. Preferably, the RF-etching process is performed using an Ar gas under the conditions of a plasma power of 400 W and a bias power of 500 W, under the conditions of a plasma power of 400 W and a bias power of 300 W or under the conditions of a plasma power of 400 W and a bias power of 100 W.

Here, through the RF-etching process, the gradient of the first phase change film 141 is decreased, and thus the aspect ratio thereof is also decreased (e.g., the gradient and aspect ratio of the recess formed over the hole are decreased), so that a subsequent phase change layer deposition process can be easily performed.

Particularly, since a phase change layer has a sputter etching rate about 10 times higher than that of a thermal oxide layer, the phase change layer can be etched using a sputtering technique without changing the phase change layer's material properties even when the etching is performed at a low bias power. In an embodiment of the present invention, the RF-etching process is conducted on the phase change layer while adjusting the bias power in order to obtain the desired etching rate of the phase change layer.

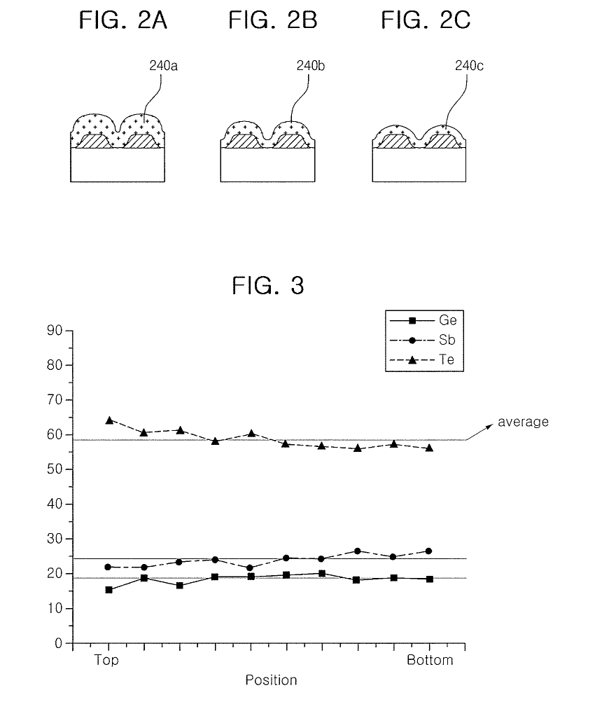

FIGS. 2A to 2C are plan views showing a state of the phase change layer after an RF etching process in the phase change memory device in accordance with the embodiment of the present invention shown in FIGS. 1A through 1C.

Referring to FIG. 2A, FIG. 2A shows a phase change layer 240a RF-etched under the conditions of a plasma power of 400 W and a bias power of 500 W.

As shown in FIG. 2B, FIG. 2B shows a phase change layer 240b RF-etched under the conditions of a plasma power of 400 W and a bias power of 300 W.

As shown in FIG. 2C, FIG. 2C shows a phase change layer 240c RF-etched under the conditions of a plasma power of 400 W and a bias power of 100 W.

When referring to FIGS. 2A through 2C, it can be seen that, when the plasma power is maintained constant, the lower the bias power the higher the etching rate of the phase change layer. That is to say, it can be seen that when the phase change layer 240a is etched under the condition of a bias power of 500 W the phase change layer 240a remains the thickest because the etching rate thereof is the lowest; and when the phase change layer 240c is etched under the condition of a bias power of 100 W the phase change layer 240a is the thinnest because the etching rate thereof is the highest.

Referring to FIG. 1D, a second phase change film 142 is deposited on the RF-etched first phase change layer 141. Preferably, the second phase change film 142 is deposited using at least two different elements selected among Ge, Sb and Te or is deposited using any one of In—Sb—Te and Ge—Bi—Te.

Meanwhile, while not shown, the second phase change film 142 is RF-etched; and subsequently, a third phase change layer can be deposited on the RF-etched second phase change layer 142. As described above, a first deposition process, an etching process and a second deposition process are performed; and then the resultant phase change layer is etched and an additional phase change layer is formed on the etched resultant phase change layer. The process of etching the resultant phase change layer and depositing an additional phase change layer on the etched resultant phase change layer can be repeated a predetermined number of times to thereby form a phase change layer.

Accordingly, in an embodiment of the present invention, a three-step process including a first deposition process of a phase change material, an RF-etching process in which the phase change material is etched, and a second deposition process in which a phase change material is deposited on the etched phase change material is performed; and at least the RF-etching process and the second deposition process are performed N times, where N may be one or greater than one, to form a phase change layer. Preferably, once the first deposition process is performed, at least the RF-etching process and the second deposition process are performed 1˜10 times to form a phase change layer. More preferably, a three-step process including the first deposition process, the RF-etching process and the second deposition process is performed; and at least the RF-etching process and the second deposition process are performed 2˜5 times to form a phase change layer.

In the present invention, since the second phase change film 142 is deposited on the first phase change film 141 in a state in which the aspect ratio of the first phase change film 141 is decreased through an RF-etching process using a bias power, a phase change layer can be formed without generating seams, compared to a phase change layer formed through only one deposition process.

Therefore, in the present invention, a stable phase change layer can be formed in narrow holes without its material properties changing according to the high integration of devices; and therefore, the characteristics of devices can be expected to be improved.

FIG. 3 is a graph showing the change in material properties of a phase change layer after an RF-etching process is performed.

As shown in FIG. 3, it can be seen that the composition ratio of a phase change material including Ge, Sb and Te in a phase change layer is not changed even when the phase change layer is RF-etched.

Referring to FIG. 1E, the first phase change film 141 and second phase change layer 142, which are formed by performing a three-step process including a first deposition process, an RF-etching process and a second deposition process N times, is planarized to expose the second interlayer dielectric 112 to form a phase change layer 140 having a confined structure in the holes 120H.

Referring to FIG. 1F, an upper electrode material is deposited on upper parts of the second interlayer dielectric 112 including the phase change layer 140 having the confined structure; and subsequently, the upper electrode material is etched so as to form upper electrodes 150 coming into contact with the phase change layer 140 having the confined structure.

Thereafter, while not shown in the drawings, by sequentially conducting a series of well-known subsequent processes, the manufacturing of a phase change memory device according to the embodiment of the present invention is completed.

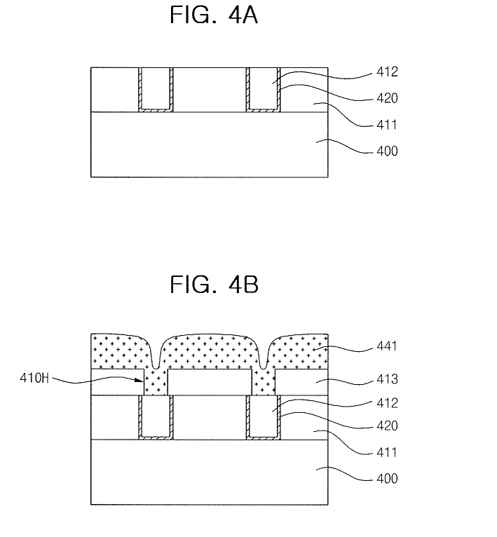

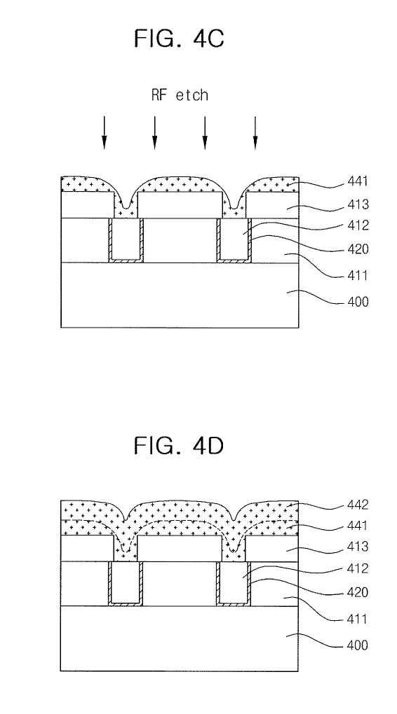

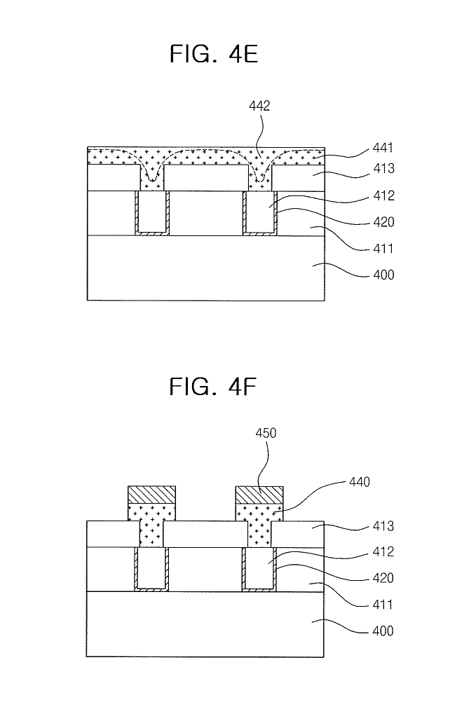

FIGS. 4A through 4F are cross-sectional views shown for illustrating the processes of a method of manufacturing a phase change memory device in accordance with another embodiment of the present invention.

Referring to FIG. 4A, a first interlayer dielectric 411 is formed on a semiconductor substrate 400 provided with a base layer (not shown). In an embodiment, the semiconductor substrate 400 includes a silicon substrate in which an n-type impurity region is formed, and the base layer includes a switching device composed of diodes. The first interlayer dielectric 411 is etched so as to define contact holes; and subsequently, a lower electrode material is deposited on the surface of the first interlayer dielectric 411 including on the surface of the contact holes in the form of a thin film. The lower electrode material is planarized to expose a portion of the interlayer dielectric 411 so as to form lower electrodes 420 on the surface of the contact holes. The lower electrodes 420 come into contact with the base layer. The lower electrodes 420 are each made of any one of W, TiN, WN, MoN, NbN, TiSiN, TiAlN, TiBN, ZrSiN, WSiN, WBN, ZrAlN, TaSiN, TaAlN, Ti, W, Ta, Pt, TiSi, TaSi, TiW, TiAlON, WON, TaON and IrO₂. A second interlayer dielectric 412 is formed to fill the contact holes; and subsequently, the second interlayer dielectric 412 is planarized to expose a portion the first interlayer dielectric 411

Referring to FIG. 4B, a third interlayer dielectric 413 is formed on the first interlayer dielectric 411 and the second interlayer dielectric 412; and subsequently, the third interlayer dielectric 413 is etched so as to define holes 410H exposing a portion of the second interlayer dielectric 412. The holes 410H are formed to a depth in the range of 300˜1500 Å; and preferably, the holes 410H are formed to a depth in the range of 1000˜1500 Å. A phase change layer is filled within the holes 410H in subsequent processes. Then, a first phase film 441 is deposited on the third interlayer dielectric 413 to fill the holes 410H. The first phase change film 441 is deposited using at least two different elements selected among Ge, Sb and Te or is deposited using any one of In—Sb—Te and Ge—Bi—Te.

Referring to FIG. 4C, an RF-etching process is conducted for on the first phase change film 441. The RF-etching process is performed using an inert gas under the condition of a bias power of 50˜500 W. Preferably, the RF-etching process is performed using Ar gas under the conditions of a plasma power of 400 W and a bias power of 500 W, under the conditions of a plasma power of 400 W and a bias power of 300 W or under the conditions of a plasma power of 400 W and a bias power of 100 W. Due to the RF-etching of the first phase change film 441, the gradient of the first phase change film 441 is decreased.

Referring to FIG. 4D, a second phase change film 442 is deposited on the RF-etched first phase change film 441. Preferably, the second phase change film 442 is deposited using at least two different elements selected among Ge, Sb and Te or is deposited using any one of In—Sb—Te and Ge—Bi—Te. The RF-etching process and the second deposition process are performed N times.

Referring to FIG. 4E, the first phase change film 441 and second phase change film 442, which are formed by performing a three-step process including a first deposition process, an RF-etching process and a second deposition, wherein at least the RF-etching process and the second deposition process are performed N times with N being once or more than once, is planarized.

Referring to FIG. 4F, an upper electrode material is deposited on the first phase change film 441 and the second phase change film 442; and subsequently, the upper electrode material is etched so as to form a phase change layer 440 having a semi-confined structure and upper electrodes 450.

Thereafter, while not shown in the drawings, by sequentially conducting a series of well-known subsequent processes, the manufacturing a phase change memory device according to the first embodiment of the present invention is completed.

As described above, in the present invention, a phase change layer can be formed without changing its composition ratio and without generating seams by performing a first deposition process, an RF-etching process using a bias power and a second deposition process, with at least the RF-etching process and the second deposition process being performed a predetermined number of times.

Therefore, in the present invention, a stable phase change layer having a confined or semi-confined structure can be formed in narrow holes in a highly integrated device, and accordingly the characteristics of devices can be expected to improve.

As described above, while the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of forming a phase change layer in a semiconductor device comprising:
(a) depositing a phase change material on a target area;
(b) etching a surface of the phase change material on the target area for a less sloped surface; and
(c) depositing additional phase change material on the etched surface of the phase change material,
wherein steps (b) and (c) are performed a N number of times, while each step of (a) to (c) is repeatable more than once.

2. The method of forming a phase change layer according to claim 1, wherein N is in the range of 2˜5.

3. The method of forming a phase change layer according to claim 1, wherein the etching process comprises an RF-etching process.

4. The method of forming a phase change layer according to claim 3, wherein the RF-etching process is performed using an inert gas.

5. The method of forming a phase change layer according to claim 4, wherein the inert gas comprises Ar.

6. The method of forming a phase change layer according to claim 3, wherein the RF-etching process is performed using a bias power of 50˜500 W.

7. The method of forming a phase change layer according to claim 3, wherein the RF-etching process is performed using a plasma power of 400 W and a bias power of 500 W.

8. The method of forming a phase change layer according to claim 3, wherein the RF-etching process is performed using a plasma power of 400 W and a bias power of 300 W.

9. The method of forming a phase change layer according to claim 3, wherein the RF-etching process is performed using a plasma power of 400 W and a bias power of 100 W.

10. The method of forming a phase change layer according to claim 1, wherein the phase change layer includes at least two different elements selected among Ge, Sb and Te, or includes any one selected among In—Sb—Te and Ge—Bi—Te.

11. A method of manufacturing a phase change memory device comprising:
forming a lower electrode;
forming an interlayer dielectric having a hole on the lower electrode;
forming a phase change layer filling the hole comprising:
(a) depositing a phase change material to fill the hole;
(b) etching a surface of the deposited phase change material filling the hole for a less sloped surface; and
(c) depositing additional phase change material on the etched surface of the phase change material filling the hole,
wherein (b) and (c) are performed a N number of times, while each step of the (a) to (c) is repeatable more than once; and
forming an upper electrode on the phase change layer.

12. The method of manufacturing a phase change memory device according to claim 11, wherein the predetermined N is in the range of 2˜5.

13. The method of manufacturing a phase change memory device according to claim 11, wherein the hole is formed to a depth in the range of 300˜1500 Å.

14. The method of manufacturing a phase change memory device according to claim 11, wherein the etching process is an RF-etching process.

15. The method of manufacturing a phase change memory device according to claim 14, wherein the RF-etching process is performed using an inert gas.

16. The method of manufacturing a phase change memory device according to claim 15, wherein the inert gas comprises Ar.

17. The method of manufacturing a phase change memory device according to claim 14, wherein the RF-etching process is performed using a bias power of 50˜500 W.

18. The method of manufacturing a phase change memory device according to claim 14, wherein the RF-etching process is performed using a plasma power of 400 W and a bias power of 500 W.

19. The method of manufacturing a phase change memory device according to claim 14, wherein the RF-etching process is performed using a plasma power of 400 W and a bias power of 300 W.

20. The method of manufacturing a phase change memory device according to claim 14, wherein the RF-etching process is performed using a plasma power of 400 W and a bias power of 100 W.

21. The method of manufacturing a phase change memory device according to claim 11, wherein the phase change layer includes at least two different elements selected among Ge, Sb and Te, or includes any one selected among In—Sb—Te and Ge—Bi—Te.

22. The method of manufacturing a phase change memory device according to claim 11, wherein the phase change layer is formed to have a confined structure or a semi-confined structure.
